(19) United States
(12) Patent Application Publication
(10) Pub. No.: US 2025/0300624 A1
(43) Pub. Date: Sep. 25, 2025

(54) BULK ACOUSTIC WAVE (BAW) PACKAGE AND METHOD OF MANUFACTURING BAW PACKAGE

(71) Applicant: WISOL CO., LTD., Gyeonggi-do (KR)

(72) Inventors: Chul Hwa LEE, Gyeonggi-do (KR); A Young MOON, Gyeonggi-do (KR); Kang Ho KIM, Gyeonggi-do (KR); Beom Jin KIM, Gyeonggi-do (KR)

(21) Appl. No.: 19/078,593

(22) Filed: Mar. 13, 2025

(30) Foreign Application Priority Data
Mar. 19, 2024 (KR) 10-2024-0037523

(51) Int. Cl. H03H 9/10; H03H 3/02; H03H 9/54; H03H 9/56

(52) U.S. Cl. CPC H03H 9/105; H03H 3/02; H03H 9/542; H03H 9/564

(57) ABSTRACT

A bulk acoustic wave (BAW) package according to an embodiment of the present disclosure comprises a BAW filter including a substrate having at least one cavity on an upper surface thereof, a lower electrode formed above the substrate, a piezoelectric layer formed above the lower electrode, and an upper electrode formed above the piezoelectric layer; and a package structure formed above the BAW filter to protect the BAW filter, wherein the package structure comprises a roof layer including a passive element and a wall layer extending vertically along edges of the roof layer.

### CROSS-REFERENCE TO RELATED APPLICATION

This application claims priority from Korean Patent Application No. 10-2024-0037523 filed on Mar. 19, 2024 in the Korean Intellectual Property Office, the contents of which in its entirety are herein incorporated by reference.

### FIELD

The present invention relates to a technique for manufacturing a package for a bulk acoustic wave (BAW) filter.

### BACKGROUND

Wireless mobile communication technology requires a variety of radio frequency (RF) components capable of efficiently transmitting information within a limited frequency band. In particular, among the RF components, a filter, which is one of the key components used in mobile communication technology, enables high-quality communication by selecting the signal required by a user from among countless airwaves or by filtering the signal intended for transmission.

Currently, the RF filters most widely used for wireless communication are dielectric filters and surface acoustic wave (SAW) filters. Dielectric filters are advantages such as high dielectric permittivity, low insertion loss, stability at high temperatures, and high resistance to vibration and shock. However, dielectric filters face limitations in terms of miniaturization and integration into Monolithic Microwave Integrated Circuits (MMICs), which are recent trends in technological development. In addition, compared to dielectric filters, SAW filters are compact, facilitate easier signal processing, and have simpler circuitry; furthermore, by employing semiconductor processes, they offer the advantage of mass production. Moreover, SAW filters exhibit higher side rejection within the passband compared to dielectric filters, which enables the transmission and reception of high-grade information. However, since the SAW filter process includes a light exposure step using ultraviolet (UV) rays, it has the drawback that the line width of an interdigital transducer (IDT) is limited to about 0.5 μm. Therefore, there is a problem that it is not possible to cover the ultra-high frequency (UHF) band (5 GHZ and above) using an SAW filter, and it is fundamentally difficult to configure an MMIC structure or a single chip on a semiconductor substrate.

To overcome the above limitations and issues, a bulk acoustic resonator (BAR) filter capable of completely making a frequency control circuit an MMIC by being integrated with other active elements on the existing silicon (Si) or gallium arsenide (GaAs) substrate has been provided.

BAW filters are thin film devices which feature a low-cost, a small size, and a high quality (high Q) coefficient, making them suitable for use in various wireless communication devices, military radar systems, and the like across a wide frequency range (900 MHz to 10 GHZ). Also, the BAW filters can be miniaturized to a size hundreds of times smaller than dielectric filters or lumped constant (LC) filters and have significantly lower insertion loss compared to SAW filters. Therefore, the BAW filters may be the most suitable devices for MMIC applications that require high stability and high-quality factors.

A BAW filter is fabricated by depositing a piezoelectric dielectric material such as zinc oxide (ZnO) or aluminum nitride (AlN) onto a semiconductor substrate, such as silicon (Si) or gallium arsenide (GaAs), using RF sputtering, and causes resonance due to the piezoelectric properties. Specifically, in a BAW filter, a piezoelectric thin film is deposited between two electrodes, and bulk acoustic waves (BAWs) are generated to induce resonance.

Traditionally, to protect such BAW filters from the external environment, wafer bonding has been used for packaging by joining a filter wafer (device) and a protective wafer (cap) using a metal material at the bonding interface.

This package structure requires a large thickness due to the use of two wafers, silicon holes formed in the protective wafer for the formation of a redistribution layer, and a large bonding layer area for bonding with the device wafer. As a result of this structure, the size and thickness of the device increase. Additionally, because the metal formation process for bonding and the formation of a silicon via layer for the redistribution layer are required, the number of process steps increases, making the manufacturing process more complex.

Conventional BAW filters are manufactured through wafer bonding using metal materials at the bonding interface between the filter wafer (device) and the protective wafer (cap) to protect the resonator portion from the external environment. The conventional structure requires a large thickness due to the use of two wafers, silicon holes formed in the protective wafer for the formation of the redistribution layer, and a large bonding layer area for bonding with the device wafer. Consequently, the size and thickness of the device increase. Additionally, because the metal formation process for bonding and the formation of a silicon via layer for the redistribution layer are required, the number of process steps increases, making the manufacturing process more complex.

In particular, conventional broadband BAW filter products are manufactured by mounting a wafer-level packaged BAW filter, which includes a capacitor, onto a printed circuit board (PCB) that includes an inductor. However, this structure requires space on a BAW filter chip to form the capacitor, leading to an increase in chip size. Moreover, to integrate the inductor into the PCB, a multilayer PCB is used, which further increases the thickness and size of the structure.

### PRIOR ART DOCUMENT

### Patent Document

(Patent Document 0001) Korean Application Publication No. 10-2004-0102390 (Published on Dec. 8, 2004)

### SUMMARY

### Technical Problem

An objective of the present invention is to provide a bulk acoustic wave (BAW) package and a method of manufacturing the same, which simplify the packaging process of a BAW filter and enable the formation of a smaller package size.

### Technical Solution

According to an aspect of the present invention, there is provided a bulk acoustic wave (BAW) package including: a BAW filter including a substrate having at least one cavity on an upper surface thereof, a lower electrode formed above the substrate, a piezoelectric layer formed above the lower electrode, and an upper electrode formed above the piezoelectric layer; and a package structure formed above the BAW filter to protect the BAW filter, wherein the package structure includes a roof layer including a passive element and a wall layer extending vertically along edges of the roof layer.

The wall layer and the roof layer may be formed of a photosensitive polymer.

The passive element may include at least one of a capacitor or an inductor.

The roof layer may include a first roof layer including the capacitor; a second roof layer including the inductor; and a metal pattern for electrically connecting the capacitor and the inductor.

The BAW package may include a protective layer formed on the package structure; and a redistribution layer which is formed along side surfaces of the roof layer, the wall layer, and the protective layer and has one end connected to the passive element through a protective layer via hole formed on an upper surface of the protective layer and the other end connected to an electrode pad formed on the BAW filter.

According to another aspect of the present invention, there is provided a method of manufacturing a BAW package, including: forming a glass wafer; forming a release layer above the glass wafer; forming a roof layer, which includes a passive element, above the release layer; forming a wall layer that extends vertically along side edges of the roof layer and encloses the roof layer, thereby completing a package structure; coupling the package structure to a BAW filter that includes a substrate, a lower electrode, a piezoelectric layer, and an upper electrode; removing the glass wafer and the release layer from the package structure; forming a protective layer on the package structure; and forming a redistribution layer to electrically connect the package structure and the BAW filter.

The wall layer and the roof layer may be formed of a photosensitive polymer.

The passive element may include at least one of a capacitor or an inductor.

The forming of the roof layer may include: forming the capacitor above the release layer; forming a first roof layer above the release layer where the capacitor has been formed; forming the inductor above the first roof layer; and forming a second roof layer above the first roof layer where the inductor has been formed.

The forming of the inductor may include forming a metal pattern for electrical connection by filling a metal material in a roof layer via hole formed in the first roof layer, and forming the inductor on the metal pattern.

The coupling of the package structure to the BAW filter may include joining one surface of the piezoelectric layer or the upper electrode, which constitutes the BAW filter, to the wall layer.

The redistribution layer may be formed along side surfaces of the roof layer, the wall layer, and the protective layer, and have one end connected to the passive element through a protective layer vial hole formed on an upper surface of the protective layer and the other end connected to an electrode pad formed on the BAW filter.

### Effects of the Invention

According to the present invention, to package a bulk acoustic wave (BAW) filter, a package structure is separately fabricated and then coupled to the BAW filter, thereby simplifying the manufacturing process of a BAW package and enabling the formation of a smaller BAW package compared to conventional packages.

In particular, in the present invention, both the capacitor and inductor, which are passive elements, are mounted on the package structure, thereby eliminating the need to mount capacitors or inductors on the BAW filter or printed circuit board (PCB), so the size and thickness of the BAW package can be minimized.

Additionally, by forming wall and roof patterns using a photosensitive polymer material on a wafer, bonding them to the BAW filter, and then debonding a release layer to transfer the wall and roof patterns and form the package, the structure and process of the BAW package are simplified and a thinner and smaller package can be formed compared to conventional packages.

### BRIEF DESCRIPTION OF THE DRAWINGS

FIG. 1 is a cross-sectional side view of a bulk acoustic wave (BAW) package according to an embodiment of the present invention.

FIG. 2 is a flowchart illustrating one embodiment of a method of manufacturing a BAW package according to the present invention.

FIG. 3 illustrates step-by-step structures of a BAW package formed through the manufacturing method shown in FIG. 2.

FIG. 4 is a flowchart illustrating an embodiment of the process of forming a roof layer.

### DETAILED DESCRIPTION

Hereinafter, exemplary embodiments of the present invention will be described in detail with reference to the accompanying drawings.

The embodiments of the present invention are provided to more completely explain the present invention to one of ordinary skill in the art. The embodiments of the present invention may be changed in a variety of shapes, and the scope of the present invention is not limited to the following embodiments. Rather, these embodiments are provided to make the present disclosure more substantial and complete and to completely transfer the concept of the present invention to those skilled in the art.

The terms used herein are to explain particular embodiments and not intended to limit the present invention. As used herein, singular forms may include plural forms unless particularly defined otherwise in context. Also, as used herein, the term “and/or” includes any and all combinations or one of a plurality of associated listed items. In addition, hereinafter, the embodiments of the present invention will be described with reference to the drawings which schematically illustrate the embodiments of the present invention.

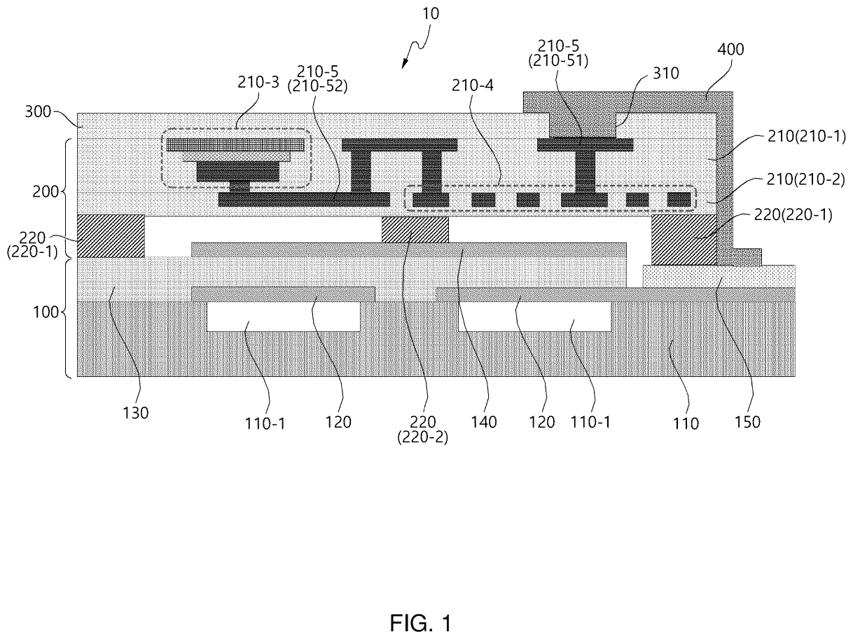

FIG. 1 is a cross-sectional side view of a bulk acoustic wave (BAW) package 10 according to an embodiment of the present invention.

Referring to FIG. 1, a BAW package 10 includes a BAW filter 100, a package structure 200, a protective layer 300, and a redistribution layer 400.

The BAW filter 100 includes a substrate 110, a lower electrode 120, a piezoelectric layer 130, an upper electrode 140, and an electrode pad 150.

When an external signal is applied between the lower electrode 120 and the upper electrode 140, a portion of electrical energy transferred between the two electrodes is converted into mechanical energy due to the piezoelectric effect and is then converted back into electrical energy. During this process, the BAW filter 100 resonates at the natural oscillation frequency depending on the thickness of the piezoelectric layer 130.

The substrate 110, which is a semiconductor substrate, may be a general silicon wafer, and preferably a high resistivity silicon (HRS) substrate. An insulating layer (not shown) may be formed on an upper surface of the substrate 110. The insulating layer may employ a thermal oxide film that can be easily grown on the substrate 110 or may selectively employ an oxide film or nitride film formed by conventional deposition processes such as chemical vapor deposition. Also, the substrate 110 includes at least one cavity 110-1 on its upper surface.

The lower electrode 120 is formed above the substrate 110 and may have a structure where it is entirely covered by the piezoelectric layer 130 or only partially covered. The lower electrode 120 may be formed above the cavity 110-1 in the substrate 110 and may completely or partially surround the upper portion of the cavity. The lower electrode 120 is formed by depositing a certain material on an upper portion of the substrate 110 and then patterning it. The material used for the lower electrode 120 is a typical conductive material such as metal, and preferably one of aluminum (Al), tungsten (W), gold (Au), platinum (Pt), nickel (Ni), titanium (Ti), chromium (Cr), palladium (Pd), or molybdenum (Mo) may be used.

The piezoelectric layer 130 is formed above the lower electrode 120 and/or the substrate 110. The piezoelectric layer 130 may be formed by depositing a piezoelectric material on the upper portion of the lower electrode 120 and then patterning it. When the piezoelectric layer 130 is formed above the lower electrode 120, it may completely cover the lower electrode 120 or partially cover it. Accordingly, the lower electrode 120 may have both a fully covered portion and a partially covered portion by the piezoelectric layer 130.

The piezoelectric material may be aluminum nitride (AlN) or zinc oxide (ZnO). The deposition method may include an RF magnetron sputtering method, an evaporation method, and the like.

The upper electrode 140 is formed above the piezoelectric layer 130. The upper electrode 140 may be formed by depositing and patterning a metal film for the upper electrode on the upper portion of the piezoelectric layer 130. The upper electrode 140 may be made of the same material as the lower electrode 120 and may be formed using the same deposition and patterning methods.

The electrode pad 150 is formed above the lower electrode 120. The electrode pad 150 is a layer for electrical connection with the package structure 200, and may be formed of a conductive metal material for this purpose.

The package structure 200 is a structure that serves to protect the BAW filter 100. To this end, the package structure 200 includes a roof layer 210 and a wall layer 220.

The roof layer 210 is a layer formed above the BAW filter 100 to protect the BAW filter 100. The roof layer 210 includes a first roof layer 210-1, a second roof layer 210-2, a capacitor 210-3, an inductor 210-4, and a metal pattern 210-5.

The first roof layer 210-1 may be formed of a photosensitive polymer. This photosensitive polymer may include photosensitive polyimide, photosensitive polybenzoxazole (PBO), epoxy, and the like. The capacitor 210-3 is a passive element electrically connected to the BAW filter 100 for operation. The capacitor 210-3 is positioned within the first roof layer 210-1. To form the capacitor 210-3 within the first roof layer 210-1, a BAW package manufacturing method, which will be described below, may be applied. Within the first roof layer 210-1, a metal pattern 210-51 is formed to electrically connect the capacitor 210-3 and the inductor 210-4.

The second roof layer 210-2 is a layer formed between the first roof layer 210-1 and the wall layer 220. The second roof layer 210-2 may also be formed of a photosensitive polymer. The inductor 210-4 is positioned within the second roof layer 210-2. To place the inductor 210-4 within the second roof layer 210-2, the BAW package manufacturing method, which will be described below, may be applied. Additionally, a metal pattern 210-52 is also formed within the second roof layer 210-2 to electrically connect the capacitor 210-3 and the inductor 210-4.

The wall layer 220 extends vertically along the edges of the roof layer 210, enclosing the roof layer 210. Additionally, the wall layer 220 may be formed in the form of a partition wall that extends vertically in a region crossing the central portion of the roof layer 210.

As shown in FIG. 1, the wall layer 220 may be in the form of an outer wall 220-1 that extends vertically along the edges of the second roof layer 210-2 and encloses the roof layer 210, or may be in the form of a partition wall 220-2 that extends vertically in a region crossing the central portion of the second roof layer 210-2, rather than along the edges of the second roof layer 210-2.

The minimum height of the wall layer 220 may be set such that the upper electrode 140, which moves in response to the vibration of the piezoelectric layer 130, does not come into contact with the roof layer 210. The wall layer 220 may also be formed of a photosensitive polymer, similar to the roof layer 210. The photosensitive polymer may include photosensitive polyimide, photosensitive polybenzoxazole (PBO), epoxy, benzocyclobutene (BCB), and the like.

As described above, the wall layer 220 has a height sufficient to prevent the upper electrode 140, which moves in response to the vibration of the piezoelectric layer 130, from coming into contact with the roof layer 210. This height allows the formation of at least one cavity between the BAW filter 110 and the package structure 200.

The protective layer 300 is a layer formed on the package structure 200. The protective layer 300 is formed above the roof layer 210 to protect the passive element contained within the roof layer, that is, the capacitor 210-3 or the metal pattern 210-5. To achieve this, the protective layer 300 may have a pattern formed using a photosensitive polymer.

The protective layer 300 includes a protective layer via hole 310 to allow the electrical connection between the capacitor 210-3 and inductor 210-4 formed in the roof layer 210 and the redistribution layer 400.

The protective layer via hole 310 has a vertically through-hole structure on one side of the protective layer 300. This protective layer via hole 310 is formed at a position corresponding to the location of the metal pattern 210-51 inside the first roof layer 210-1. As a result, the metal pattern 210-51 inside the first roof layer 210-1 can be exposed to the outside.

When the protective layer via hole 310 is formed at a position corresponding to the metal pattern 210-51 inside the first roof layer 210-1, one end of the redistribution layer 400 may be filled into the protective layer via hole 310.

The redistribution layer 400 is a layer that serves to electrically connect the passive element contained in the roof layer 210 of the package structure 200 with the electrode pad 150 formed on the BAW filter 100. To this end, the redistribution layer 400 is formed of a conductive metal material, such as Cu, Ni, Au, Sn, or the like.

The redistribution layer 400 is formed along the side surfaces of the roof layer 210, the wall layer 220, and the protective layer 300. Additionally, one end of the redistribution layer 400 is connected to the passive component through the protective layer via hole 310 formed on the upper surface of the protective layer 300, while the other end is connected to the electrode pad 150 formed on the BAW filter 100.

As shown in FIG. 1, one end of the redistribution layer 400 is connected to the metal pattern 210-5 that electrically connects the capacitor 210-3 and the inductor 210-4 formed in the roof layer 210 through the protective layer via hole 310 of the protective layer 300. The other end of the redistribution layer 400 is connected to the electrode pad 150 formed on the lower electrode 120 of the BAW filter 100.

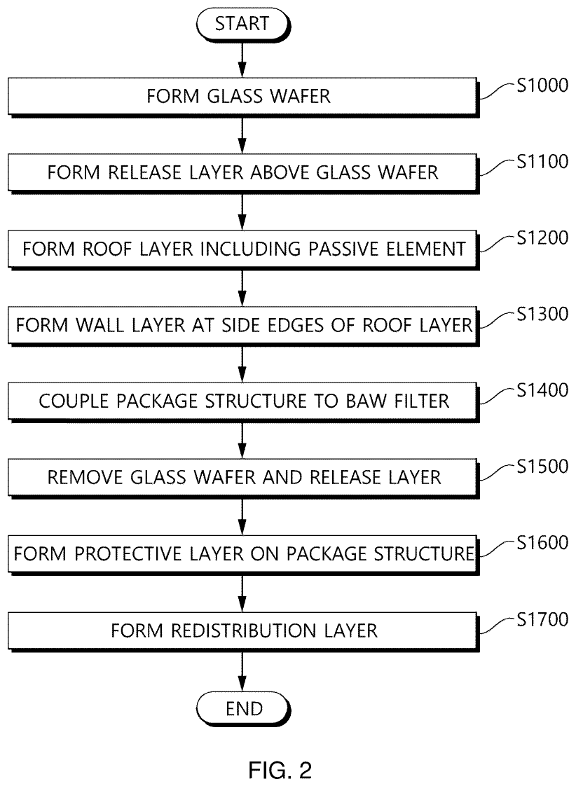

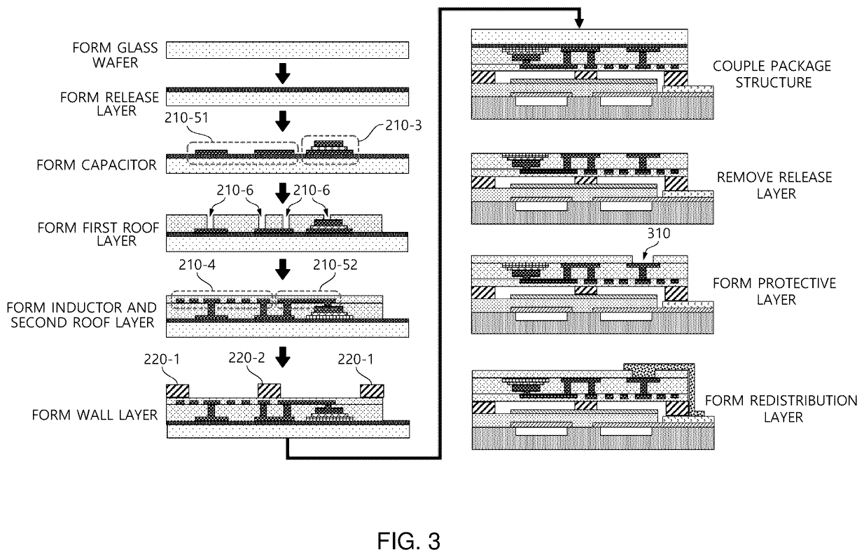

FIG. 2 is a flowchart illustrating an embodiment of a method of manufacturing a BAW package according to the present invention, and FIG. 3 illustrates the step-by-step structures of a BAW package formed through the manufacturing method shown in FIG. 2.

First, a glass wafer for a package structure is formed (step S1000). The glass wafer may be made of borosilicate glass, which has a thermal expansion coefficient similar to silicon and allows laser wavelengths to pass through.

After step S1000, a release layer is formed above the glass wafer (step S1100). The release layer is used for the later removal of the glass wafer. The release layer may be made of a polymer material that reacts with a laser, causing its polymer bonds to break.

After step S1100, a roof layer, which includes a passive element, is formed above the release layer (step S1200). Here, the passive element may include a capacitor and an inductor.

The roof layer may be formed of a photosensitive polymer. This photosensitive polymer may include photosensitive polyimide, photosensitive polybenzoxazole (PBO), epoxy, BCB, and the like.

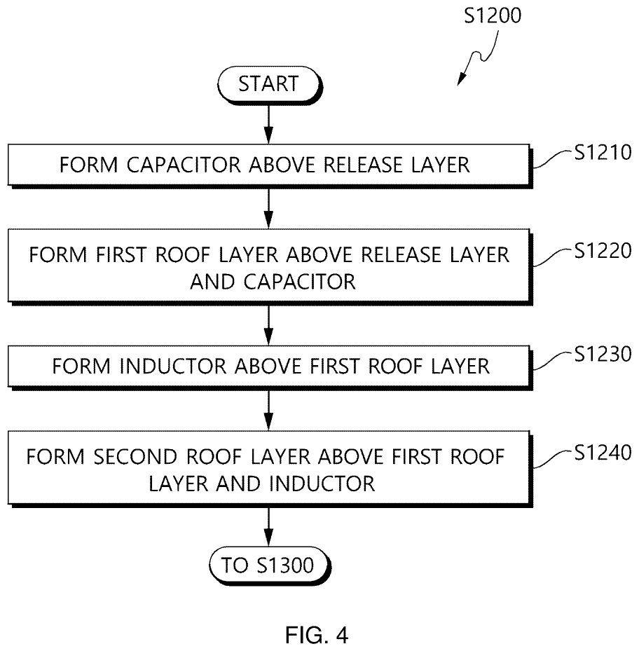

FIG. 4 is a flowchart illustrating an embodiment of the process of forming the roof layer.

First, a capacitor, which is one of the passive elements, is formed above the release layer (step S1210).

When forming the capacitor, a metal pattern for electrically connecting the capacitor and inductor to the redistribution layer may be formed together. As shown in FIG. 3, the capacitor 210-3 and the metal pattern 210-51 are formed above the release layer.

After step S1210, a first roof layer is formed above the release layer where the capacitor has been already formed (step S1220). The first roof layer is formed with a certain minimum thickness on the release layer to cover the capacitor and the metal pattern. Then, to fill in a metal material for electrically connecting the capacitor 210-3, a roof layer via hole 210-6 is formed in the first roof layer 210.

As shown in FIG. 3, the roof layer via hole 210-6 may have a through-hole structure that vertically penetrates the first roof layer 210. The roof layer via hole 210-6 may be formed at a position corresponding to each of the capacitor 210-3 and the metal pattern 210-51. The roof layer via holes 210-6 penetrate vertically and make contact with the capacitor 210-3 and the metal pattern 210-51.

After step S1220, an inductor is formed above the first roof layer (step S1230). Before forming the inductor 210-4 above the first roof layer, the roof layer via hole 210-6 formed in step S1220 is filled with a metal material for forming the metal pattern. Here, the metal material includes any conductive metal.

Then, the inductor 210-4 is formed above the first roof layer, where the metal material has already been filled. When forming the inductor 210-4 above the first roof layer, an additional metal pattern 210-52 may also be formed to electrically connect the inductor 210-4 and the capacitor 210-3 to the redistribution layer. As shown in FIG. 3, both the inductor 210-4 and the metal pattern 210-52 are formed above the first roof layer.

After step S1230, a second roof layer is formed above the first roof layer, where the inductor has been formed (step S1240). The second roof layer is formed with a certain minimum thickness on the first roof layer to cover the inductor 210-4 and the metal pattern 210-52.

After step S1200, a wall layer is formed that extends vertically along the edges of the second roof layer and encloses the second roof layer, thereby completing the package structure (step S1300). The wall layer may also be formed of a photosensitive polymer, similar to the roof layer.

The wall layer may be in the form of an outer wall 220-1 that extends vertically along the edges of the second roof layer and encloses the roof layer. Additionally, the wall layer may include a partition wall 220-2 that extends vertically in a region crossing the central portion of the roof layer, rather than along the side edges of the roof layer. The minimum height of the wall layer may be set such that the upper electrode, which moves in response to the vibration of the piezoelectric layer, does not come into contact with the roof layer.

After step S1300, the package structure including the roof layer and the wall layer is coupled to a BAW filter (step S1400).

The wall layer of the package structure is coupled to the piezoelectric layer or upper electrode, which constitutes the BAW filter.

Referring to FIGS. 1 and 3, the wall layer formed at the side edges of the roof layer is joined at its end to the upper surface of the piezoelectric layer, which constitutes the BAW filter. The wall layer formed at the central portion of the roof layer is joined at its end to the upper surface of the upper electrode, which constitutes the BAW filter. At this time, the photosensitive polymer constituting the wall layer may be bonded to both the piezoelectric layer and the upper electrode of the BAW filter through adhesion.

After step S1400, the glass wafer and the release layer are removed from the package structure (step S1500). The glass wafer is separated by irradiating the release layer with a laser to break its polymer bonds, and the remaining release layer left on the roof layer may then be removed using a wet solution or ashing.

After step S1500, a protective layer is formed on the package structure (step S1600). The protective layer is formed on the surface of the package structure, where the glass wafer and release layer have been removed. The protective layer serves to protect the capacitor and the metal pattern, which are exposed due to the removal of the glass wafer and release layer.

After forming the protective layer, a protective layer via hole is formed so that the metal pattern previously formed on the package structure can be connected to the redistribution layer.

After forming the protective layer, a protective layer via hole 310 is formed as a vertically through-hole on one side of the protective layer. This protective layer via hole 310 is formed at a position corresponding to the location of the metal pattern formed inside the roof layer.

After step S1600, a redistribution layer is formed to electrically connect the package structure and the BAW filter (step S1700). The redistribution layer is formed along the side surfaces of the roof layer, the wall layer, and the protective layer.

At this time, one end of the redistribution layer is connected to the passive element through the protective layer via hole formed on the upper surface of the protective layer, while the other end is connected to the electrode pad formed on the BAW filter.

Referring to FIGS. 1 to 3, one end of the redistribution layer is connected to the metal pattern through the protective layer via hole, while being in horizontal contact with the upper surface of the roof layer. The other end of the redistribution layer is connected to the upper surface of the electrode pad, which is formed on the lower electrode of the BAW filter, while being in horizontal contact.

The exemplary embodiments of the present invention have been described above. One of ordinary skill in the art may understand that modifications may be made without departing from the scope of the present invention. Therefore, the disclosed embodiments should be considered in a descriptive aspect not a limitative aspect. The scope of the present invention will be shown in the claims not in the foregoing description, and all differences within an equivalent scope thereof should be construed as being included in the present invention.

### REFERENCE NUMERALS

10: BAW PACKAGE
100: BAW FILTER
200: PACKAGE STRUCTURE
300: PROTECTIVE LAYER
400: REDISTRIBUTION LAYER

What is claimed:

1. A bulk acoustic wave (BAW) package comprising:
a BAW filter comprising a substrate having at least one cavity on an upper surface thereof, a lower electrode formed above the substrate, a piezoelectric layer formed above the lower electrode, and an upper electrode formed above the piezoelectric layer; and
a package structure formed above the BAW filter to protect the BAW filter,
wherein the package structure comprises a roof layer including a passive element and a wall layer extending vertically along edges of the roof layer.

2. The BAW package of claim 1, wherein the wall layer and the roof layer are formed of a photosensitive polymer.

3. The BAW package of claim 1, wherein the passive element comprises at least one of a capacitor or an inductor.

4. The BAW package of claim 1, wherein the roof layer comprises
a first roof layer including the capacitor;
a second roof layer including the inductor; and
a metal pattern for electrically connecting the capacitor and the inductor.

5. The BAW package of claim 1, comprising:
a protective layer formed on the package structure; and
a redistribution layer which is formed along side surfaces of the roof layer, the wall layer, and the protective layer and has one end connected to the passive element through a protective layer via hole formed on an upper surface of the protective layer and the other end connected to an electrode pad formed on the BAW filter.

6. A method of manufacturing a bulk acoustic wave (BAW) package, comprising:
forming a glass wafer;
forming a release layer above the glass wafer;
forming a roof layer, which comprises a passive element, above the release layer;
forming a wall layer that extends vertically along side edges of the roof layer and encloses the roof layer, thereby completing a package structure;
coupling the package structure to a BAW filter that comprises a substrate, a lower electrode, a piezoelectric layer, and an upper electrode;
removing the glass wafer and the release layer from the package structure;
forming a protective layer on the package structure; and
forming a redistribution layer to electrically connect the package structure and the BAW filter.

7. The method of claim 6, wherein the wall layer and the roof layer are formed of a photosensitive polymer.

8. The method of claim 6, wherein the passive element comprises at least one of a capacitor or an inductor.

9. The method of claim 8, wherein the forming of the roof layer comprises
forming the capacitor above the release layer;
forming a first roof layer above the release layer where the capacitor has been formed;
forming the inductor above the first roof layer; and
forming a second roof layer above the first roof layer where the inductor has been formed.

10. The method of claim 9, wherein the forming of the inductor comprises forming a metal pattern for electrical connection by filling a metal material in a roof layer via hole formed in the first roof layer, and forming the inductor on the metal pattern.

11. The method of claim 6, wherein the coupling of the package structure to the BAW filter comprises joining one surface of the piezoelectric layer or the upper electrode, which constitutes the BAW filter, to the wall layer.

12. The method of claim 6, wherein the redistribution layer is formed along side surfaces of the roof layer, the wall layer, and the protective layer, and has one end connected to the passive element through a protective layer vial hole formed on an upper surface of the protective layer and the other end connected to an electrode pad formed on the BAW filter.
